(19) United States
(12) Patent Application Publication
(10) Pub. No.: US 2015/0114827 A1
(43) Pub. Date: Apr. 30, 2015

(54) METHODS OF FORMING A METAL DIELECTRIC ETCHING STOP LAYER ON A SUBSTRATE WITH HIGH ETCHING SELECTIVITY

(71) Applicant: Applied Materials, Inc., Santa Clara, CA (US)

(72) Inventors: Yong CAO, San Jose, CA (US); Tingjun XU, San Jose, CA (US); Rajkumar JAKKARAJU, San Jose, CA (US); Rongjun WANG, Dublin, CA (US)

(21) Appl. No.: 14/062,610

(22) Filed: Oct. 24, 2013

(51) Int. Cl. H01L 21/02; C23C 14/34

(52) U.S. Cl. CPC H01L 21/02266; H01L 21/02178; C23C 14/34
USPC 204/192.22

(57) ABSTRACT

Methods for forming a metal dielectric etching stop layer onto a substrate with good etching selectivity and low wet etching rate. In one embodiment, a method of sputter depositing a metal dielectric etching stop layer on the substrate includes transferring a substrate in a processing chamber, supplying a gas mixture including at least N₂ gas into the processing chamber, applying a RF power to form a plasma from the gas mixture to sputter source material from a target disposed in the processing chamber, maintaining a substrate temperature less than about 320 degrees Celsius, and depositing a metal dielectric etching stop layer onto the substrate from the sputtered source material.

### BACKGROUND OF THE DISCLOSURE

1. Field of the Invention

Embodiments of the invention generally relate to a fabrication process for forming a metal dielectric layer on a substrate, and more particularly, for forming a metal dielectric layer that may be utilized as an etching stop layer during a semiconductor manufacturing process.

2. Description of the Background Art

Reliably producing submicron and smaller features is one of the key technologies for the next generation of very large scale integration (VLSI) and ultra large scale integration (ULSI) of semiconductor devices. However, as the miniaturization of circuit technology is pressed, the shrinking dimensions of interconnects in VLSI and ULSI technology have placed additional demands on the processing capabilities. The multilevel interconnects that lie at the heart of this technology require precise processing of high aspect ratio features, such as vias and other interconnects. Reliable formation of these interconnects is very important to VLSI and ULSI success and to the continued effort to increase circuit density and quality of individual substrates.

As circuit densities increase for next generation devices, the widths of interconnects, such as vias, trenches, contacts, gate structures and other features, as well as the dielectric materials therebetween, decrease to 45 nm and 32 nm dimensions, whereas the thickness of the dielectric layers remain substantially constant, with the result of increasing the aspect ratios of the features.

In order to enable fabrication of next generation devices and structures, three dimensional (3D) stacking of semiconductor chips is often utilized to improve performance of the transistors. By arranging transistors in three dimensions instead of conventional two dimensions, multiple transistors may be placed in the integrated circuits (ICs) very close to each other. Three dimensional (3D) stacking of semiconductor chips reduces wire lengths and keeps wiring delay low. In manufacturing three dimensional (3D) stacking of semiconductor chips, multiple film layer structures are often utilized to allow multiple interconnection structures to be disposed thereon, forming high-density of vertical transistor devices.

In the manufacture of high density semiconductor chips, a metal dielectric layer, such as a titanium nitride or a tantalum nitride layer, is often used as a liner barrier or an etching stop layer disposed under the multiple layer structures. In some embodiments, a dielectric insulating layer has been utilized as an etching stop layer of three dimensional (3D) stacking of semiconductor chips to reduce leakage current. The titanium nitride layer or the tantalum nitride layer may be used to provide contacts to the source and drain of a transistor, a gate electrode disposed in a gate structure or a barrier layer between a dielectric layer and a metal layer. The titanium nitride layer or the tantalum nitride layer may be used as a barrier layer to inhibit the diffusion of metals into regions underlying the dielectric layer in a gate structure, contact structure or back end interconnection structure.

When utilizing a metal dielectric film layer as an etching stop layer, the metal dielectric film layer is required to have a film property dissimilar to the adjacent layers, so as to provide a high selectivity during etching. Poor selectivity between the metal dielectric etching stop layer and the other layers of the film stack disposed above may result in over-etching, poor pattern transfer and failure to maintain accurate dimension control. Accordingly, the metal dielectric etching stop layer is often required to provide an etching stop interface that may provide a high etching selectivity to assist protecting the overlying layers from damage while reduce likelihood of over-etching.

Furthermore, thicker metal dielectric etching stop layers may provide relatively better etching selectivity and also limit or control impurity diffusion. However, the resistance of a metal dielectric etching stop layer increases proportional to the thickness, as does the time and cost for deposition.

Therefore, there is a need for an improved method of forming a metal dielectric etching top layer with good etching selectivity, desired surface morphology and desired film properties.

### SUMMARY OF THE INVENTION

The present invention provides methods for forming a metal dielectric etching stop layer onto a substrate with good etching selectivity. The metal dielectric etching stop layer may be formed by a sputtering deposition process using a low temperature less than 320 degrees Celsius. In one embodiment, a method of sputter depositing a metal dielectric etching stop layer on the substrate includes transferring a substrate in a processing chamber, supplying a gas mixture including at least N₂ gas into the processing chamber, applying a DC or RF power to form a plasma from the gas mixture to sputter source material from a target disposed in the processing chamber, maintaining a substrate temperature less than about 320 degrees Celsius, and depositing a metal dielectric etching stop layer onto the substrate from the sputtered source material.

In another embodiment, a method of sputter depositing a metal dielectric layer on the substrate includes transferring a substrate in a processing chamber, supplying a gas mixture including at least an O₂ gas and a N₂ gas into the processing chamber, applying a DC or RF power in the gas mixture to form a plasma and sputter materials from a target, controlling a substrate temperature less than 250 degrees Celsius, and depositing a metal dielectric etching stop layer onto the substrate.

In yet another embodiment, a method of sputter depositing a metal dielectric etching stop layer on the substrate includes transferring a substrate in a processing chamber, supplying a gas mixture including at least N₂ and O₂ gas into the processing chamber, wherein the gas mixture has a gas flow ratio of the O₂ gas to N₂ gas between about 1:5 and about 5:1, applying a DC or RF power to form a plasma from the gas mixture to sputter source material from a target disposed in the processing chamber, maintaining a substrate temperature between about 50 degrees Celsius and about 200 degrees Celsius, and depositing a layer of aluminum oxynitride onto the substrate from the sputtered source material.

### BRIEF DESCRIPTION OF THE DRAWINGS

So that the manner in which the above recited features of the present invention are attained and can be understood in detail, a more particular description of the invention, briefly summarized above, may be had by reference to the embodiments thereof which are illustrated in the appended drawings.

FIG. 1 depicts a schematic cross-sectional view for a film stack including a metal dielectric etching stop layer in accordance with the invention;

FIG. 2 depicts a schematic cross-sectional view of one embodiment of a process chamber in accordance with the invention;

FIG. 3 depicts a process flow diagram for depositing a metal dielectric etching stop layer in accordance with one embodiment of the present invention; and

FIG. 4A-4B depicts an exemplary cross sectional view of a metal dielectric etching stop layer formed on a substrate at different manufacture stage accordance with one embodiment of the present invention.

To facilitate understanding, identical reference numerals have been used, where possible, to designate identical elements that are common to the figures. It is contemplated that elements and features of one embodiment may be beneficially incorporated in other embodiments without further recitation.

It is to be noted, however, that the appended drawings illustrate only exemplary embodiments of this invention and are therefore not to be considered limiting of its scope, for the invention may admit to other equally effective embodiments.

### DETAILED DESCRIPTION

The present invention provides methods for depositing a metal dielectric etching stop layer onto a substrate having a film property with high etching selectivity to dielectric layers. The deposition process may be a sputtering deposition process, e.g., a physical vapor deposition process, that utilizes a low substrate temperature, such as less than 320 degrees Celsius, for example, between about −20 degrees Celsius and about 320 degrees Celsius, or such as less than about 250 degrees Celsius. The deposition process may include supplying at least a nitrogen containing gas along with an inert gas into the processing chamber while controlling the substrate temperature less than about 320 degrees Celsius, for example about less than 250 degrees Celsius. By controlling a substrate temperature at a desired range, along with the gas mixture supplied during the deposition process, a robust film structure may be obtained that provides good etching selectivity between the metal dielectric etching stop layer and a dielectric film stack disposed thereon during etching.

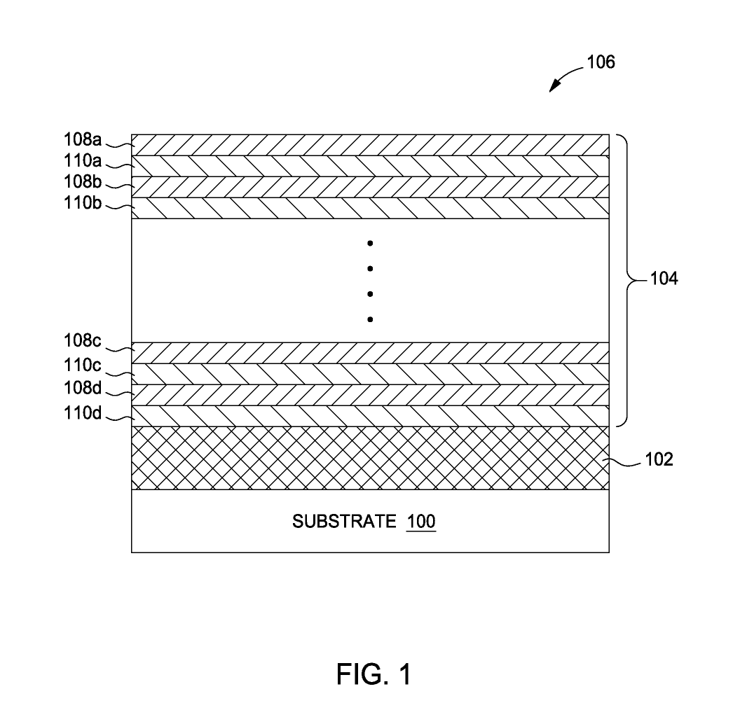

FIG. 1 depicts an exemplary film stack 104 disposed on a metal dielectric etching stop layer 102 which is disposed on a substrate 100. The film stack 104 may be configured to form a gate structure 106 on the substrate 100. The film stack 104 includes at least a first dielectric layer 108a, 108b, 108c, 108d and a second dielectric layer 110a, 110b, 110c, 110d. Although the embodiment depicted in FIG. 1 shows four pairs of the first dielectric layer 108a, 108b, 108c, 108d and the second dielectric layer 110a, 110b, 110c, 110d (alternating first dielectric layer 108a, 108b, 108c, 108d and second dielectric layer 110a, 110b, 110c, 110d repeatedly formed on the metal dielectric etching stop layer 102), it is noted that number of the first dielectric layer and the second dielectric layer may be varied based on different process needs. In one particular embodiment, fifteen pairs of the first dielectric layer and the second dielectric layer pairs may be formed on the metal dielectric etching stop layer 102 configured to form a gate structure. In one embodiment, the thickness of each single first dielectric layer 108a may be controlled at between about 1 Å and about 10 Å, such as about 4 Å, and the thickness of the each single second dielectric layer 110a may be controlled at between about 1 Å and about 10 Å, such as about 4 Å. The film stack 104 may have a total thickness between about 10 Å and about 500 Å.

In one embodiment, each of the first dielectric layers 108a, 108b, 108c, 108d is a silicon oxide layer and each of the second dielectric layers 110a, 110b, 110c, 110d is a silicon nitride layer, or vise versa. In another embodiment, the first dielectric layer 108a, 108b, 108c, 108d is a silicon oxide layer and the second dielectric layer 110a, 110b, 110c, 110d is a polysilicon layer, or doped silicon layer, metal containing dielectric layers, or vise versa.

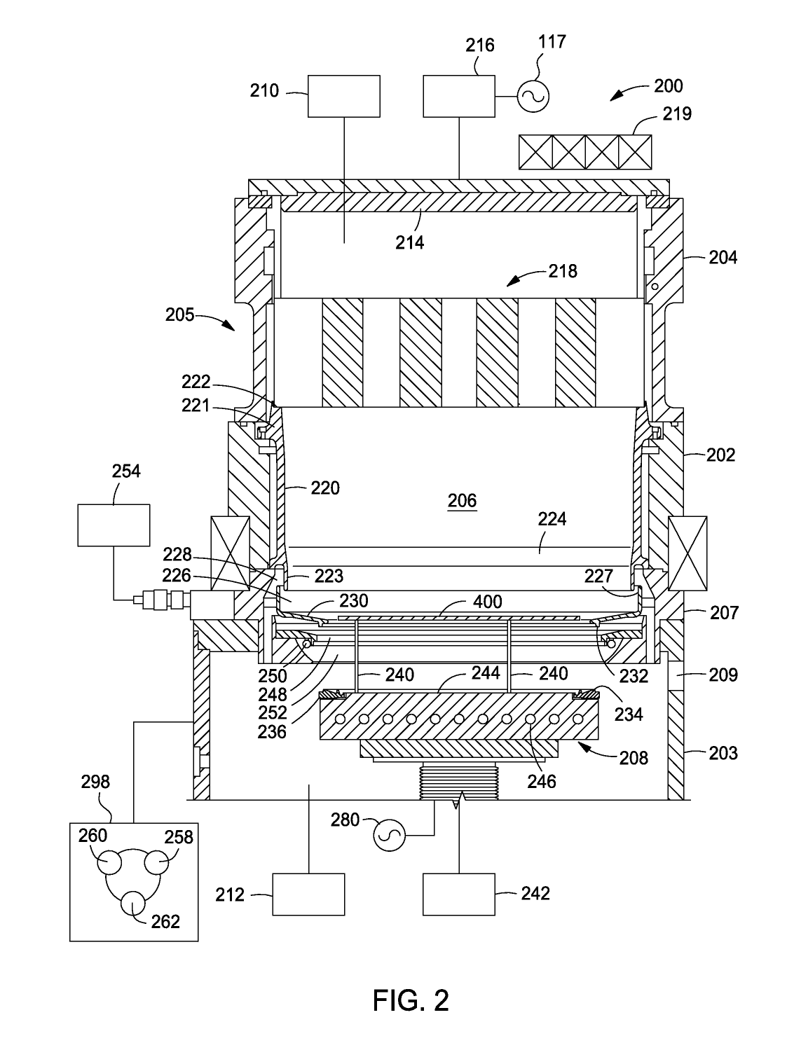

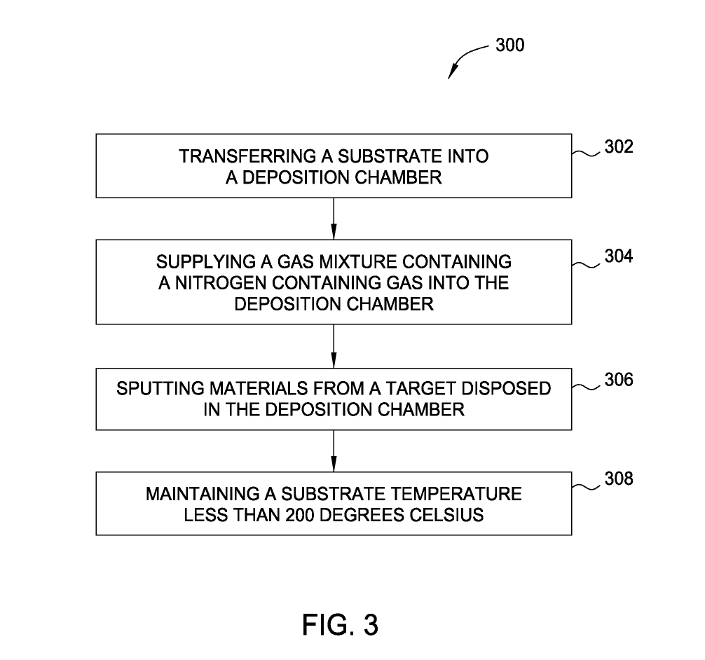

The metal dielectric etching stop layer 102 may be a metal dielectric layer, such as aluminum oxide, aluminum oxynitride, aluminum nitride, tantalum oxide, tantalum nitride, tantalum oxynitride, titanium oxide, titanium nitride, titanium oxynitride, or other suitable metal dielectric layer. In one example, the metal dielectric etching stop layer 102 may be deposited by the processing chamber described below with referenced to FIG. 2 by utilizing the method described in FIG. 3 below.

FIG. 2 illustrates an exemplary physical vapor deposition (PVD) chamber 200 (e.g., a sputter process chamber) suitable for sputter depositing materials according to one embodiment of the invention. Examples of suitable PVD chambers include the ALPS® Plus and SIP ENCORE® PVD processing chambers, both commercially available from Applied Materials, Inc., Santa Clara, of California. It is contemplated that processing chambers available from other manufactures may also be adapted to perform the embodiments described herein.

FIG. 2 is a schematic cross-sectional view of a deposition chamber 200 according to one embodiment. The deposition chamber 200 has an upper sidewall 202, a lower sidewall 203, and a lid portion 204 defining a body 205 that encloses an interior volume 206 thereof. An adapter plate 207 may be disposed between the upper sidewall 202 and the lower sidewall 203. A substrate support, such as a pedestal 208, is disposed in the interior volume 206 of the deposition chamber 200. A substrate transfer port 209 is formed in the lower sidewall 203 for transferring substrates into and out of the interior volume 206.

In one embodiment, the deposition chamber 200 comprises a sputtering chamber, also known as a physical vapor deposition (PVD) chamber, capable of depositing, for example, titanium, aluminum oxide, aluminum, aluminum oxynitride, copper, tantalum, tantalum nitride, tantalum oxynitride, titanium oxynitride, tungsten, or tungsten nitride on a substrate, such as the substrate 400.

A gas source 210 is coupled to the deposition chamber 200 to supply process gases into the interior volume 206. In one embodiment, process gases may include inert gases, non-reactive gases, and reactive gases if necessary. Examples of process gases that may be provided by the gas source 210 include, but not limited to, argon gas (Ar), helium (He), neon gas (Ne), nitrogen gas (N₂), oxygen gas (O₂), and H₂O among others.

A pumping device 212 is coupled to the deposition chamber 200 in communication with the interior volume 206 to control the pressure of the interior volume 206. In one embodiment, the pressure level of the deposition chamber 200 may be maintained at about 1 Torr or less. In another embodiment, the pressure level of the deposition chamber 200 may be maintained at about 500 milliTorr or less. In yet another embodiment, the pressure level of the deposition chamber 200 may be maintained at about 1 milliTorr and about 300 milliTorr.

The lid portion 204 may support a sputtering source 214, such as a target. In one embodiment, the sputtering source 214 may be fabricated from a material containing titanium (Ti) metal, tantalum metal (Ta), tungsten (W) metal, cobalt (Co), nickel (Ni), copper (Cu), aluminum (Al), alloys thereof, combinations thereof, or the like. In an exemplary embodiment depicted herein, the sputtering source 214 may be fabricated by titanium (Ti) metal, tantalum metal (Ta) or aluminum (Al).

The sputtering source 214 may be coupled to a source assembly 216 comprising a power supply 117 for the sputtering source 214. A set of magnet 219 may be coupled adjacent to the sputtering source 214 which enhances efficient sputtering materials from the sputtering source 214 during processing. Examples of the magnetron assembly include an electromagnetic linear magnetron, a serpentine magnetron, a spiral magnetron, a double-digitated magnetron, a rectangularized spiral magnetron, among others.

An additional RF power source 280 may also coupled to the deposition chamber 200 through the pedestal 208 to provide a bias power between the sputtering source 214 and the pedestal 208 as needed. In one embodiment, the RF power source 280 may have a frequency between about 1 MHz and about 100 MHz, such as about 13.56 MHz.

A collimator 218 may be positioned in the interior volume 206 between the sputtering source 214 and the pedestal 208. A shield tube 220 may be in proximity to the collimator 218 and interior of the lid portion 204. The collimator 218 includes a plurality of apertures to direct gas and/or material flux within the interior volume 206. The collimator 218 may be mechanically and electrically coupled to the shield tube 220. In one embodiment, the collimator 218 is mechanically coupled to the shield tube 220, such as by a welding process, making the collimator 218 integral to the shield tube 220. In another embodiment, the collimator 218 may be electrically floating within the chamber 200. In another embodiment, the collimator 218 may be coupled to an electrical power source and/or electrically coupled to the lid portion 204 of the body 205 of the deposition chamber 200.

The shield tube 220 may include a tubular body 221 having a recess 222 formed in an upper surface thereof. The recess 222 provides a mating interface with a lower surface of the collimator 218. The tubular body 221 of the shield tube 220 may include a shoulder region 223 having an inner diameter that is less than the inner diameter of the remainder of the tubular body 221. In one embodiment, the inner surface of the tubular body 221 transitions radially inward along a tapered surface 224 to an inner surface of the shoulder region 223. A shield ring 226 may be disposed in the chamber 200 adjacent to the shield tube 220 and intermediate of the shield tube 220 and the adapter plate 207. The shield ring 226 may be at least partially disposed in a recess 228 formed by an opposing side of the shoulder region 223 of the shield tube 220 and an interior sidewall of the adapter plate 207.

In one aspect, the shield ring 226 includes an axially projecting annular sidewall 227 that includes an inner diameter that is greater than an outer diameter of the shoulder region 223 of the shield tube 220. A radial flange 230 extends from the annular sidewall 227. The radial flange 230 may be formed at an angle greater than about ninety degrees (90°) relative to the inside diameter surface of the annular sidewall 227 of the shield ring 226. The radial flange 230 includes a protrusion 232 formed on a lower surface thereof. The protrusion 232 may be a circular ridge extending from the surface of the radial flange 230 in an orientation that is substantially parallel to the inside diameter surface of the annular sidewall 227 of the shield ring 226. The protrusion 232 is generally adapted to mate with a recessed flange 234 formed in an edge ring 236 disposed on the pedestal 208. The recessed flange 234 may be a circular groove formed in the edge ring 236. The engagement of the protrusion 232 and the recessed flange 234 centers the shield ring 226 with respect to the longitudinal axis of the pedestal 208. The substrate 400 (shown supported on lift pins 240) is centered relative to the longitudinal axis of the pedestal 208 by coordinated positioning calibration between the pedestal 208 and a robot blade (not shown). In this manner, the substrate 400 may be centered within the deposition chamber 200 and the shield ring 226 may be centered radially about the substrate 400 during processing.

In operation, a robot blade (not shown) having a substrate 400 thereon is extended through the substrate transfer port 209. The pedestal 208 may be lowered to allow the substrate 400 to be transferred to the lift pins 240 extending from the pedestal 208. Lifting and lowering of the pedestal 208 and/or the lift pins 240 may be controlled by a drive 242 coupled to the pedestal 208. The substrate 400 may be lowered onto a substrate receiving surface 244 of the pedestal 208. With the substrate 400 positioned on the substrate receiving surface 244 of the pedestal 208, sputter deposition may be performed on the substrate 400. The edge ring 236 may be electrically insulated from the substrate 400 during processing. Therefore, the substrate receiving surface 244 may include a height that is greater than a height of portions of the edge ring 236 adjacent the substrate 400 such that the substrate 400 is prevented from contacting the edge ring 236. During sputter deposition, the temperature of the substrate 400 may be controlled by utilizing thermal control channels 246 disposed in the pedestal 208.

After sputter deposition, the substrate 400 may be elevated utilizing the lift pins 240 to a position that is spaced away from the pedestal 208. The elevated location may be proximate one or both of the shield ring 226 and a reflector ring 248 adjacent to the adapter plate 207. The adapter plate 207 includes one or more lamps 250 coupled thereto intermediate of a lower surface of the reflector ring 248 and a concave surface 252 of the adapter plate 207. The lamps 250 provide optical and/or radiant energy in the visible or near visible wavelengths, such as in the infra-red (IR) and/or ultraviolet (UV) spectrum. The energy from the lamps 250 is focused radially inward toward the backside (i.e., lower surface) of the substrate 400 to heat the substrate 400 and the material deposited thereon. Reflective surfaces on the chamber components surrounding the substrate 400 serve to focus the energy toward the backside of the substrate 400 and away from other chamber components where the energy would be lost and/or not utilized. The adapter plate 207 may be coupled to a coolant source 254 to control the temperature of the adapter plate 207 during heating.

After controlling the substrate 400 to the desired temperature, the substrate 400 is lowered to a position on the substrate receiving surface 244 of the pedestal 208. The substrate 400 may be rapidly cooled utilizing the thermal control channels 246 in the pedestal 208 via conduction. The temperature of the substrate 400 may be ramped down from the first temperature to a second temperature in a matter of seconds to about a minute. The substrate 400 may be removed from the deposition chamber 200 through the substrate transfer port 209 for further processing. The substrate 400 may be maintained at a desired temperature range, such as less than 250 degrees Celsius as needed.

A controller 298 is coupled to the process chamber 200. The controller 298 includes a central processing unit (CPU) 260, a memory 258, and support circuits 262. The controller 298 is utilized to control the process sequence, regulating the gas flows from the gas source 210 into the deposition chamber 200 and controlling ion bombardment of the sputtering source 214. The CPU 260 may be of any form of a general purpose computer processor that can be used in an industrial setting. The software routines can be stored in the memory 258, such as random access memory, read only memory, floppy or hard disk drive, or other form of digital storage. The support circuits 262 are conventionally coupled to the CPU 260 and may comprise cache, clock circuits, input/output subsystems, power supplies, and the like. The software routines, when executed by the CPU 260, transform the CPU into a specific purpose computer (controller) 298 that controls the deposition chamber 200 such that the processes are performed in accordance with the present invention. The software routines may also be stored and/or executed by a second controller (not shown) that is located remotely from the chamber 200.

During processing, material is sputtered from the sputtering source 214 and deposited on the surface of the substrate 400. The sputtering source 214 and the substrate support pedestal 208 are biased relative to each other by the power supply 117 or 280 to maintain a plasma formed from the process gases supplied by the gas source 210. The ions from the plasma are accelerated toward and strike the sputtering source 214, causing target material to be dislodged from the sputtering source 214. The dislodged target material and process gases forms a layer on the substrate 400 with desired compositions.

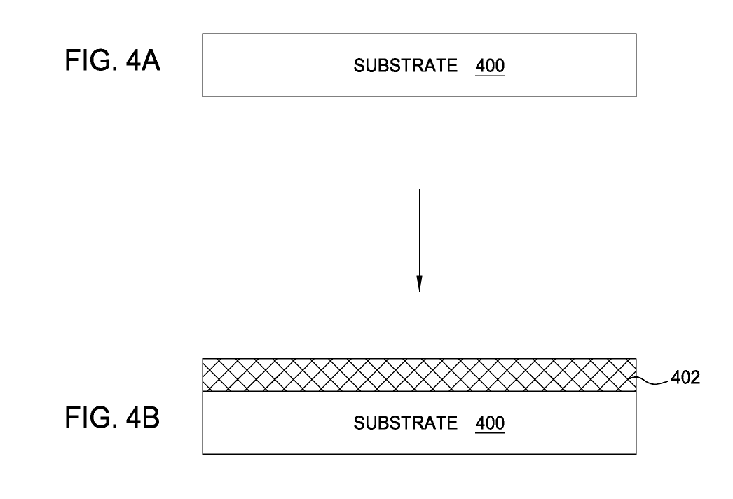

FIG. 3 depicts a process 300 of forming and depositing a metal dielectric etching stop layer onto a substrate surface. FIGS. 4A-4B depict schematic cross-sectional views of an exemplary application sequence of a metal dielectric etching stop layer 402 formed on the substrate 400 by utilizing the process 300. After the etching stop layer 402, similar to the metal dielectric etching stop layer 102 described in FIG. 1, a film stack, such as the film stack 104 described above in FIG. 1, may then be disposed on the metal dielectric etching stop layer 402.

The process 300 starts at step 302 by transferring the substrate 400 having a desired feature formed thereon into a process chamber, such as the deposition chamber 200, as depicted in FIG. 2. “Substrate” or “substrate surface,” as used herein, refers to any substrate or material surface formed on a substrate upon which film processing is performed. For example, a substrate surface on which processing can be performed include materials such as silicon, silicon oxide, strained silicon, silicon on insulator (SOI), carbon doped silicon oxides, silicon nitride, doped silicon, germanium, gallium arsenide, glass, sapphire, quartz, and any other materials such as metals, metal nitrides, metal alloys, and other conductive materials, depending on the application. Barrier layers, metals or metal nitrides on a substrate surface may include titanium, titanium nitride, titanium silicide nitride, tungsten, tungsten nitride, tungsten silicide nitride, tantalum, tantalum nitride, or tantalum silicide nitride. Substrates may have various dimensions, such as 200 mm, 300 mm or 450 mm diameter wafers, as well as, rectangular or square panes. Substrates include semiconductor substrates, display substrates (e.g., LCD), solar panel substrates, and other types of substrates. Unless otherwise noted, embodiments and examples described herein are conducted on substrates with a 200 mm diameter, a 300 mm diameter or a 450 mm diameter. Processes of the embodiments described herein may be used to form or deposit titanium nitride materials on many substrates and surfaces. Substrates on which embodiments of the invention may be useful include, but are not limited to semiconductor wafers, such as crystalline silicon (e.g., Si<100> or Si<111>), silicon oxide, glass, quartz, strained silicon, silicon germanium, doped or undoped polysilicon, doped or undoped silicon wafers and patterned or non-patterned wafers. Substrates may be exposed to a pretreatment process to polish, etch, reduce, oxidize, hydroxylate, anneal and/or bake the substrate surface.

At step 304, a gas mixture is supplied to the deposition chamber 200 to form a metal dielectric etching stop layer 402 onto the substrate 400, as shown in FIG. 4B. In one embodiment, the gas mixture may include reactive gas, non-reactive gas, inert gas, and the like. Examples of reactive and non-reactive gas include, but not limited to, O₂, N₂, N₂O, NO₂, NH₃, and H₂O, among others. Examples of inert gas include, but not limited to, Ar, Ne, He, Xe, and Kr, among others. In one particular embodiment depicted herein, the gas mixture supplied to the process chamber includes at least one nitrogen containing gas, an oxygen containing gas and optionally an inert gas.

In one embodiment, the gas mixture supplied to the processing chamber 200 for deposition of the metal dielectric etching stop layer 402 includes at least an oxygen containing gas, such as O₂, H₂O, NO₂ or N₂O, and a nitrogen containing gas, such as N₂, NO₂, N₂O, NH₃, and the like. In one example, the gas mixture supplied to the deposition chamber 200 for deposition of the metal dielectric etching stop layer 402 includes a O₂ gas and a N₂ gas. During processing, a metal alloy target is utilized as the sputtering source 214. For example, a metal alloy target made from an aluminum (Al) containing alloy may be utilized as a source material for the sputtering source 214 for sputter process. It is noted that the aluminum (Al) containing target as described here is only for illustration propose and should not be construed as limiting the scope of the invention. Furthermore, the metal alloy target that may be utilized as the sputtering source 214 may be made by a material from a group consisting of Cu, Ti, Ta, W, Co, Cr, Ni, alloys thereof, combinations thereof and the like.

In one embodiment, the gas mixture supplied into the process chamber 200 includes an O₂ gas and a N₂ gas. The O₂ gas may be supplied at a flow rate between about 1 sccm and about 1000 sccm. The N₂ gas flow may be controlled at a flow rate between about 1 sccm and about 1000 sccm. In the embodiment wherein an inert gas, such as He or Ar, is utilized, the inert gas may be supplied in the gas mixture at a flow rate between about 1 sccm and about 1000 sccm.

In one embodiment, the O₂ gas and the N₂ gas supplied in the gas mixture may be regulated at a predetermined ratio to form the metal dielectric etching stop layer 402, such as a AlOₓN_{y} layer, when the sputtering source 214 utilized here is an aluminum target. Under the predetermined ratio of the O₂ gas and the N₂ gas supplied in the gas mixture, a predetermined stoichiometric ratio of nitrogen and oxygen may be formed in the resultant AlOₓN_{y} layer. It is believed that by controlling the ratio of O₂ gas to the N₂ gas supplied in the gas mixture, different ratios of the oxygen and nitrogen elements may be utilized to control the stoichiometric ratio of nitrogen and oxygen formed in the resultant AlOₓN_{y} layer. It is believed that the nitrogen elements formed in the AlOₓN_{y} layer may enhance the etching selectivity to the dielectric layers to be formed on the AlOₓN_{y} layer. Also, it is found that higher ratio of the nitrogen elements formed in the AlOₓN_{y} layer has a lower wet etching rate (i.e., an indication of high etching selectivity), indicating the film structure is more rigid in the high nitrogen ratio AlOₓN_{y} layer, as compared to the AlOₓN_{y} layer having a lower ratio of the nitrogen elements. Thus, a good control of gas flow ratio between the O₂ gas and the N₂ gas may result in a AlOₓN_{y} layer with more desirable film properties such as having a desired range of etching selectivity and a high wet etching rate.

In one embodiment, during the deposition the ratio of the N₂ gas as supplied in the gas mixture relative to the total amount of gas as supplied in the gas mixture may be controlled at a flow rate less than 50 percent. It is believed that a high ratio of the N₂ gas supplied in the gas mixture can assist having a good film rigidity that enhances etching selectivity. In the embodiment, the ratio of the N₂ gas to the O₂ gas supplied in the gas mixture is controlled at a flow rate less than 50 percent, such as between about 5:1 to about 1:5.

At step 306, after the gas mixture is supplied into the deposition chamber 200 for processing, a high voltage power is supplied to the sputtering source 214, for example a Al target, to sputter the metal Al source material from the sputtering source 214 in form of aluminum ions, such as Al³⁺. The bias power applied between the sputtering source 214 and the substrate support pedestal 208 maintains a plasma formed from the gas mixture in the process chamber 200. The ions mainly from the gas mixture in the plasma bombard and sputter off material from the sputtering source 214. The gas mixture and/or other process parameters may be varied during the sputtering deposition process, thereby creating a gradient with desired film properties for different film quality requirements.

During processing, several process parameters may be regulated. In one embodiment, the DC or RF source power may be supplied between about 100 Watts and about 20000 Watts. A RF bias power may be applied to the substrate support between about 50 Watts and about 5000 Watts.

At step 308, during the sputtering deposition, a substrate temperature may be controlled at a range less than about 320 degrees Celsius, such as 250 degrees Celsius. In the conventional high substrate temperature sputtering process having a substrate temperature greater than about 400 degrees Celsius, it is believed that the high substrate temperature may assist raising the deposition rate. However, such conventional process may adversely form a AlOₓN_{y} layer having a relatively porous structure, thereby reducing the rigidity of the resultant film structure. The porous structure of the AlOₓN_{y} layer may adverse reducing etching selectivity, thereby increasing the likelihood of over-etching and inaccurate etching stop endpoint. Therefore, by reducing the substrate temperature less than about 320 degrees Celsius, for example less than 250 degrees Celsius, the deposition rate may be slightly reduced, allowing the atomic structures of the AlOₓN_{y} metal dielectric etching stop layer 402 formed on the substrate 400 to be closely packed, thereby creating a dense and robust metal dielectric etching stop layer 402 with high etching selectivity. In one embodiment, by controlling the substrate temperature less than about 250 degrees Celsius, a desired film property of the metal dielectric etching stop layer 402 may be obtained with desired low etching rate and etching high selectivity.

In one embodiment, during deposition, the deposition rate may be controlled between about 1 nm per minute and about 100 nm per minute. The resultant AlOₓN_{y} layer may have a high selectivity to the dielectric film stack to be disposed thereon of greater than 100, such as between about 1:1 and about 200:1. The x and y value in the AlOₓN_{y} layer may be integers ranging from 1 to 10. In one embodiment, the ratio of x to y (e.g., the ratio of the oxygen elements to the nitrogen element formed in the resultant AlOₓN_{y} layer) is between about 5:1 to 1:5, such as about 1:2 and about 2:1, for example about 1.04:1. Furthermore, the wet etching rate of the resultant AlOₓN_{y} layer may be less than 5 nm per minute in a 2000:1 by volume in HF solution (e.g., 1 unit of HF in 2000 unit of DI water by volume.

After the metal dielectric etching stop layer 402 is formed on the substrate 400, a film stack, such as the film stack 104 depicted in FIG. 1 having repeated first dielectric layers and the second dielectric layers, may be then deposited on the substrate 400, utilizing the metal dielectric etching stop layer 402 as an etching stop layer during an etching process. The film stack disposed on the substrate 400 may be utilized to form a gate structure in a memory application.

Thus, methods for forming a metal dielectric etching stop layer onto a substrate with high etching selectivity and low wet etching rate are provided. The deposition process may include supplying at least an nitrogen containing gas during processing while maintaining a low substrate temperature less than about 250 degrees Celsius. By adjusting the gas ratio and maintaining the substrate at a low temperature range, a high etching selectivity and low wet etching rate metal dielectric etching stop layer may be obtained.

While the foregoing is directed to embodiments of the present invention, other and further embodiments of the invention may be devised without departing from the basic scope thereof, and the scope thereof is determined by the claims that follow.

What is claimed is:

1. A method of sputter depositing a metal dielectric etching stop layer on the substrate, comprising:
transferring a substrate in a processing chamber;
supplying a gas mixture including at least N₂ gas into the processing chamber;
applying a DC or RF power to form a plasma from the gas mixture to sputter source material from a target disposed in the processing chamber;
maintaining a substrate temperature less than about 320 degrees Celsius; and
depositing a metal dielectric etching stop layer onto the substrate from the sputtered source material.

2. The method of claim 1, wherein supplying the gas mixture further comprises:
supplying O₂ gas in the gas mixture.

3. The method of claim 2, wherein a gas flow ratio of the O₂ gas to N₂ gas is between about 1:5 and about 5:1.

4. The method of claim 1, wherein maintaining the substrate temperature further comprises:
maintaining the substrate temperature between about 50 degrees Celsius and about 200 degrees Celsius.

5. The method of claim 1, wherein applying the RF power further comprises:
applying a RF bias power to a substrate support pedestal disposed in the processing chamber having the substrate is positioned thereon.

6. The method of claim 1, wherein the target is fabricated from at least one of Al, Ti, Ta, W, Cr, Ni, Cu, Co, alloys thereof, or combinations thereof.

7. The method of claim 1, wherein the target is fabricated from Al.

8. The method of claim 1, further comprising:
forming a film stack on the metal dielectric etching stop layer, the film stack including at least a first dielectric layer disposed on a second dielectric layer.

9. The method of claim 8, wherein the film stack includes repeated pairs of first and the second dielectric layers.

10. The method of claim 8, wherein the first dielectric layer is a silicon oxide layer and the second dielectric layer is a silicon nitride layer or a polysilicon layer.

11. The method of claim 1, wherein the metal dielectric etching stop layer is an aluminum oxynitride layer having a ratio of nitrogen element to oxygen element between about 5:1 and 1:5.

12. A method of sputter depositing a metal dielectric layer on the substrate, comprising:
transferring a substrate in a processing chamber;
supplying a gas mixture including at least an O₂ gas and a N₂ gas into the processing chamber;
applying a RF power in the gas mixture to form a plasma and sputter materials from a target;
controlling a substrate temperature less than 250 degrees Celsius; and
depositing a metal dielectric etching stop layer onto the substrate.

13. The method of claim 12, wherein the gas mixture further includes Ar gas.

14. The method of claim 12, wherein a gas flow ratio of the O₂ gas to N₂ gas in the gas mixture is between about 1:5 and about 5:1.

15. The method of claim 12, wherein the target is fabricated from at least one of Al, Ti, Ta, W, Cr, Ni, Cu, Co, alloys thereof, or combinations thereof.

16. The method of claim 12, wherein applying the RF power in the gas mixture further comprises:
applying a RF bias power to a substrate support pedestal disposed in the processing chamber where the substrate is positioned thereon.

17. The method of claim 12, wherein the metal dielectric etching stop layer is an aluminum oxynitride layer having a ratio of nitrogen element to oxygen element between about 5:1 and 1:5.

18. The method of claim 12, further comprising:
forming a film stack on the metal dielectric etching stop layer, the film stack including at least a first dielectric layer disposed on a second dielectric layer.

19. The method of claim 18, wherein the first dielectric layer is a silicon oxide layer and the second dielectric layer is a silicon nitride layer or a polysilicon layer.

20. A method of sputter depositing a metal dielectric etching stop layer on the substrate, comprising:
transferring a substrate in a processing chamber;
supplying a gas mixture including at least N₂ and O₂ gas into the processing chamber, wherein the gas mixture has a gas flow ratio of the O₂ gas to N₂ gas between about 1:5 and about 5:1;
applying a RF power to form a plasma from the gas mixture to sputter source material from a target disposed in the processing chamber;
maintaining a substrate temperature between about 50 degrees Celsius and about 200 degrees Celsius; and
depositing a layer of aluminum oxynitride onto the substrate from the sputtered source material.
